(19) United States
(12) Patent Application Publication
(10) Pub. No.: US 2012/0238088 A1
(43) Pub. Date: Sep. 20, 2012

(54) FABRICATION METHOD OF METAL GATES FOR GATE-LAST PROCESS

(76) Inventors: Jinjuan Xiang, Beijing (CN); Wenwu Wang, Beijing (CN)

(21) Appl. No.: 13/513,160

(22) PCT Filed: Sep. 28, 2011
(86) PCT No.: PCT/CN2011/080300

§ 371 Date: May 31, 2012

(30) Foreign Application Priority Data
Sep. 29, 2010 (CN) 201010500383.0
Sep. 28, 2011 (CN) PCT/CN2011/080300

(51) Int. Cl. H01L 21/285

(52) U.S. Cl. 438/592; 257/E21.161

(57) ABSTRACT

A method for fabricating metal gates using a gate-last process, comprising: providing a substrate (20), the substrate comprising a gate trench (30); performing at least one metal layer deposition and one annealing on the surface of the substrate to fill a metal layer (32) in the gate trench; and removing the metal layer outside of the gate trench. This method can reduce the parasitic resistance of the gates and improve the reliability of the transistors.

This application is a National Stage application of, and claims priority to, international application PCT/CN2011/080300 filed on Sep. 28, 2011, which claimed priority to Chinese patent application 201010500383.0 filed on Sep. 29, 2010. Both the PCT international application and the Chinese application are incorporated herein by reference in their entireties.

### FIELD OF THE INVENTION

The present invention relates to the field of semiconductor technology, and more particularly to a method for manufacturing a metal gate in a gate-last process.

### BACKGROUND OF THE INVENTION

Currently, in the manufacturing procedure of integrated circuits, gate manufacturing in CMOS technology at the 22 nm technology node and beyond generally comprises a gate-first process and a gate-last process.

The gate-first process comprises: firstly depositing a gate dielectric layer, and forming a gate on the gate dielectric layer; then performing source/drain implantation; and performing annealing to activate the ions in the source/drain, to form a source region and a drain region. The gate-first process has an advantage of simple procedures; however, it also has a disadvantage that the gate has to suffer high temperature during the annealing process, which may cause threshold voltage Vt drift in the transistor and affect electrical performance of the device.

The gate-last process comprises: firstly depositing a gate dielectric layer, and forming a dummy gate (e.g., polycrystalline silicon) on the gate dielectric layer; then forming a source region and a drain region; then removing the dummy gate to form a gate groove; and filling the gate groove with a suitable metal to form a metal gate. Thus, the high temperature brought by the formation of the source region and the drain region can be avoided to the gate electrode, thereby reducing threshold voltage Vt drift in transistor, improving the electrical performance of the device in comparison with the gate-first process.

However, in CMOS technology at the 22 nm technology node and beyond, the width of the gate groove may become so small that the filling result of the metal material cannot meet certain requirements, e.g., there maybe gaps or holes exist in the metal filled in the gate groove, which may increase the parasitic resistance and cause problems such as degradation of the reliability of the transistor.

### SUMMARY OF THE INVENTION

A problem to be solved by the present invention is providing a method for manufacturing a metal gate in a gate-last process, which may reduce the parasitic resistance of the gate and improve the reliability of the transistor. In order to solve the problems mentioned above, according to the present invention, a method for manufacturing a metal gate in a gate-last process is provided, comprising:

providing a substrate, the substrate comprising a gate groove;

performing a metal layer depositing-annealing process on a surface of the substrate for at least once, to fill the gate groove with a metal layer; and

removing a portion of the metal layer that is outside the gate groove.

The step of performing a metal layer depositing-annealing process on a surface of the substrate for at least once to fill the gate groove with a metal layer comprises:

depositing a metal layer on a surface of the substrate, to fill the gate groove; and

performing annealing on the metal layer, to modify filling topography inside the gate groove.

Preferably, the material of the metal layer is Al or TiAlₓ.

Optionally, the metal layer comprises:

at least two element-metal layers, the element-metal layers being stacked from bottom to top in the order of decreasing melting points.

Optionally, the step of performing a metal layer depositing-annealing process on a surface of the substrate for at least once comprises the steps of:

depositing a metal sublayer on a surface of the substrate;

performing annealing on the metal sublayer, to modify filling topography of the metal sublayer, thereby completing a cycle of the depositing-annealing process; and

performing at least two cycles of the depositing-annealing process.

Preferably, the material of the metal sublayer is Al or TiAlₓ.

Optionally, the metal sublayer comprises:

at least two element-metal layers, the element-metal layers being stacked from bottom to top in the order of decreasing melting points.

Preferably, the materials of the element-metal layers are Ti and Al from bottom to top.

Preferably, the annealing is performed in N₂ or He.

Preferably, the annealing is performed at a temperature ranging from 300 to 600 degrees Celsius

Preferably, Physical vapor deposition (PVD) or Chemical vapor deposition (CVD) is used to deposit the metal layer in the metal layer depositing-annealing process.

In comparison with the prior art, the present invention may bring the following advantages:

By performing a metal layer depositing-annealing process for at least once, i.e., by firstly filling the gate groove with a metal material and then performing annealing on the metal material, due to the fluidity characteristic of metal materials under an annealing temperature, filling topography of the metal inside the gate groove can be improved, thereby improving filling performance of the metal and reducing gaps and holes in the filled metal layer.

As compared with Atomic Layer Deposition (ALD), which has good shape-retaining performance, but is limited in its application in metal gate manufacturing due to its limited types of precursor source for metal layer deposition, the metal layer deposition according to the embodiment of the present invention can be performed using conventional PVD or CVD, consequently, almost every metal can be deposited. By depositing a metal material with low resistivity and good electrical conductivity in the gate groove using PVD or CVD and then performing annealing, the filling performance of the metal inside the gate groove can be improved, thereby reducing the parasitic resistance of the gate and improving the reliability of the transistor.

### BRIEF DESCRIPTION OF THE DRAWINGS

FIG. 1 is a flow chart of a method for manufacturing a metal gate in a gate-last process according to a first embodiment;

FIGS. 2a to 2h are schematic diagrams illustrating a method for manufacturing a metal gate in a gate-last process according to the first embodiment;

FIG. 3 is a flow chart of a method for manufacturing a metal gate in a gate-last process according to a second embodiment;

FIGS. 4a to 4d are schematic diagrams illustrating a method for manufacturing a metal gate in a gate-last process according to the second embodiment;

FIG. 5 is a flow chart of a method for manufacturing a metal gate in a gate-last process according to a third embodiment;

FIGS. 6a to 6d are schematic diagrams illustrating a method for manufacturing a metal gate in a gate-last process according to the third embodiment;

FIG. 7 is a flow chart of a method for manufacturing a metal gate in a gate-last process according to a fourth embodiment; and

FIGS. 8a to 8g are schematic diagrams illustrating a method for manufacturing a metal gate in a gate-last process according to the first embodiment.

### DETAILED DESCRIPTION OF THE INVENTION

According to an embodiment of the present invention, a method for manufacturing a metal gate in a gate-last process is provided, and the method comprises: providing a substrate, the substrate comprising a gate groove; performing a metal layer depositing-annealing process on a surface of the substrate for at least once, to fill the gate groove with a metal layer; and removing a portion of the metal layer that is outside the gate groove.

In the method described above for manufacturing a metal gate, by performing a metal layer depositing-annealing process for at least once, i.e., by firstly filling the gate groove with a metal material and then performing annealing on the metal material, due to the fluidity characteristic of metal materials under an annealing temperature, filling topography of the metal inside the gate groove can be improved, thereby improving filling performance of the metal and reducing gaps and holes in the filled metal layer.

As compared with Atomic Layer Deposition (ALD), which has good shape-retaining performance, but is limited in its application in metal gate manufacturing due to its limited types of precursor source for metal layer deposition, the metal layer deposition according to the embodiment of the present invention can be performed using conventional PVD or CVD, consequently, almost every metal can be deposited. By depositing a metal material with low resistivity and good electrical conductivity in the gate groove using PVD or CVD and then performing annealing, the filling performance of the metal inside the gate groove can be improved, thereby reducing the parasitic resistance of the gate and improving the reliability of the transistor.

For a better understanding of the objects, features and advantages of the present invention described above, the embodiments of the present invention will be described hereinafter in detail with the accompanying drawings as reference.

Numerous specific details are set forth in the following descriptions, in order to provide a thorough understanding of the present invention. It will be apparent to one skilled in the art that the present invention may be practiced without these specific details, and that equivalent details to the present invention may be obtained without deviation from the essence of the present invention. Hence, the present invention is not limited to the embodiments disclosed herein.

In addition, the present invention is described in detail in conjunction with the accompanying drawings. In the detailed descriptions of the embodiments of the present invention, for illustrative purposes, the sectional views illustrating device structures may be enlarged locally without maintaining their normal proportions; and the accompanying drawings are merely examples, which should not be considered as limiting the scope of the present invention. Moreover, in an actual manufacturing process, three dimensions, i.e., length, width and depth, should be included.

### First Embodiment

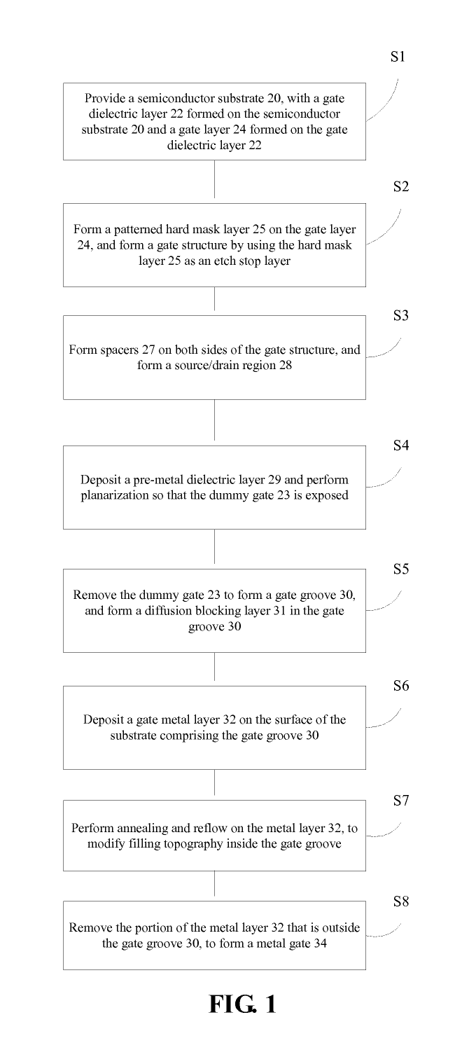

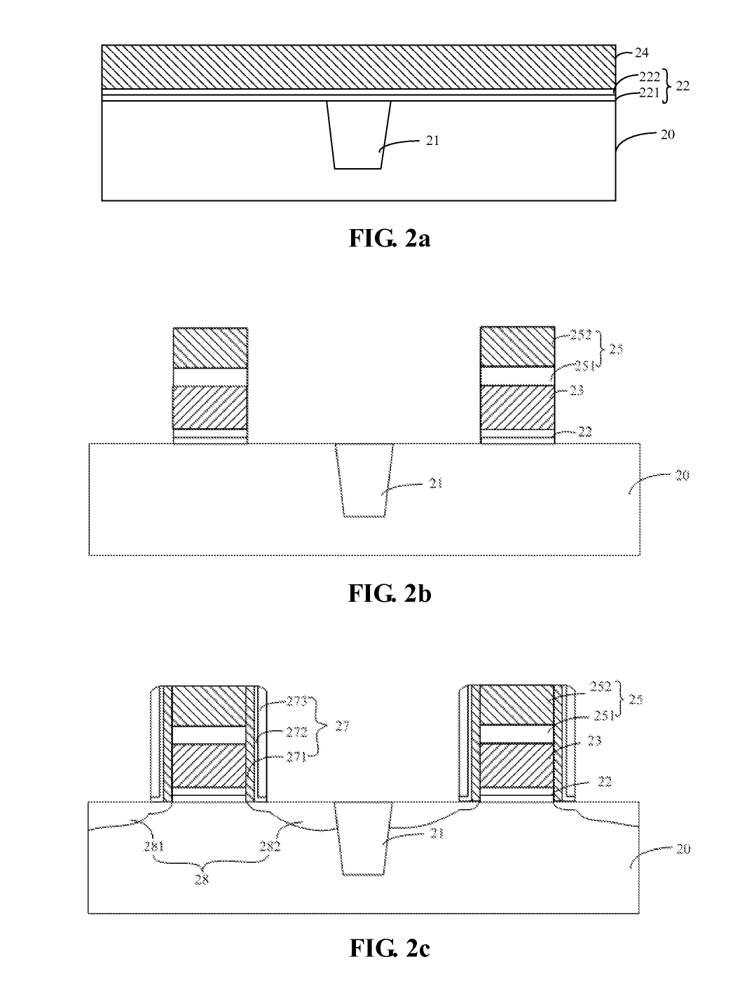

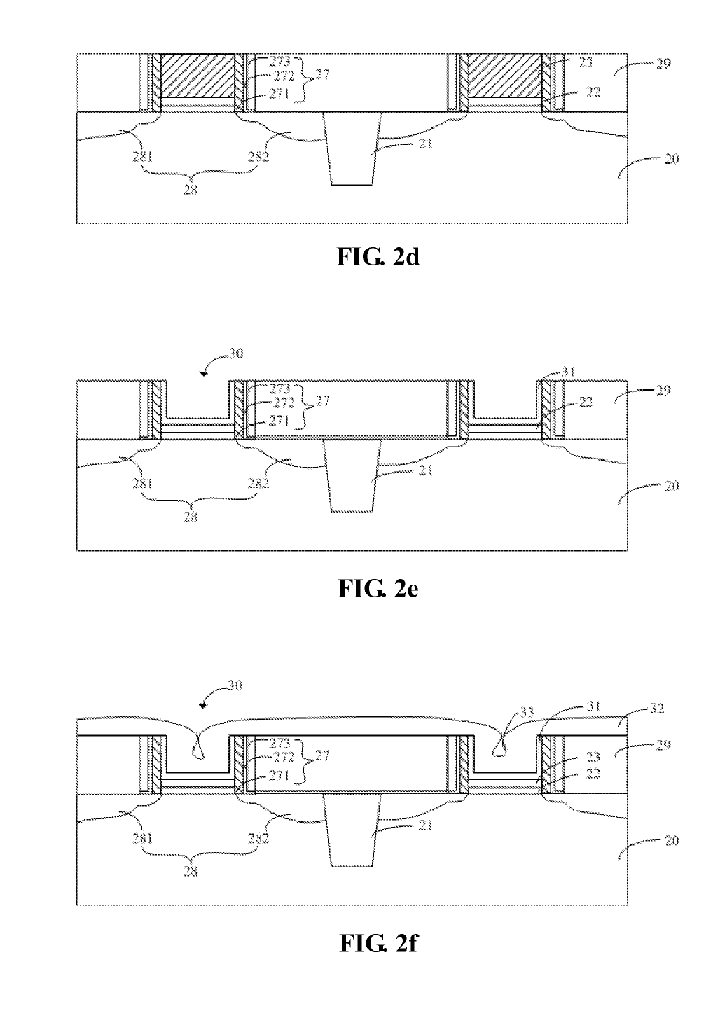

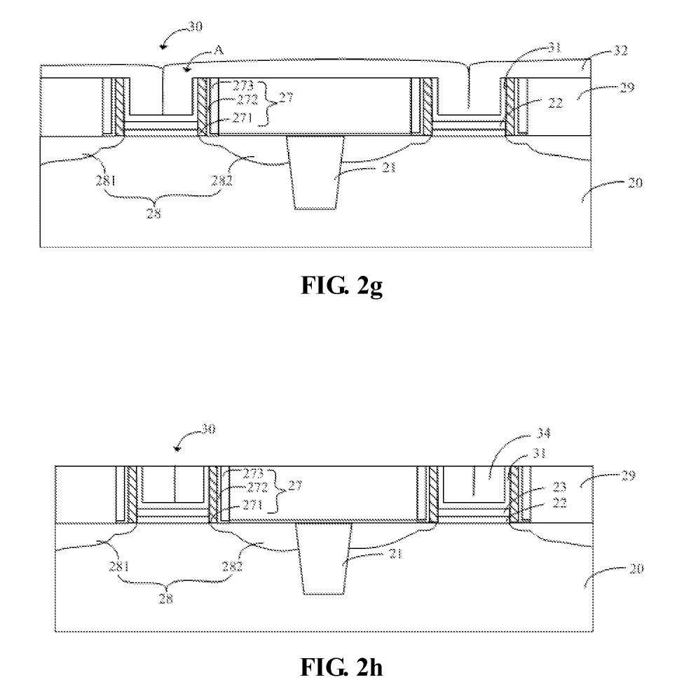

FIG. 1 is a flow chart of a method for manufacturing a metal gate in a gate-last process according to this embodiment; and FIGS. 2a to 2h are schematic diagrams illustrating a method for manufacturing a metal gate in a gate-last process according to the embodiment.

As shown in FIG. 1, the method for manufacturing a metal gate in a gate-last process comprises the following steps:

Step S1: a semiconductor substrate 20 is provided, with a gate dielectric layer 22 formed on the semiconductor substrate 20 and a gate layer 24 formed on the gate dielectric layer 22.

Specifically, referring to FIG. 2a, the material of the semiconductor substrate 20 may be monocrystalline silicon (Si), monocrystalline germanium (Ge), Silicon-germanium (SiGe) or Silicon carbide (SiC); may be Silicon-On-Insulator (SOI) or Germanium-On-Insulator (GOI); or, may also be another material, for example, an III-V compound such as gallium arsenide.

A shallow trench isolation region 21 may be formed in a surface of the semiconductor substrate 20 by a Shallow Trench Isolation (STI) process, for isolating active regions formed subsequently.

After the formation of the shallow trench isolation region 21, a gate dielectric layer 22 may be deposited on the semiconductor substrate 20. In this embodiment, the gate dielectric layer 22 may comprise a gate oxide layer 221 and a high dielectric constant (high-K) dielectric layer 222 (e.g., any one or a combination of: HfO₂, HfSiO, HfSiON, HfTaO, HfTiO, HfZrO, Al₂O₃, La₂O₃, ZrO₂, and LaAlO) stacked sequentially. The material of the gate oxide layer 221 may be silicon oxide or silicon oxynitride, and its thickness may be about 0.1 nm to 1 nm. In other embodiments, the material of the gate oxide layer 221 may also be another material known to those skilled in the art. The material of the high-K dielectric layer 222 may be Hafnium Oxide (HfO2) with a high dielectric constant, and its thickness may be about 1 nm to 5 nm. In other embodiments, the material of the high-K dielectric layer 222 may also be another material known to those skilled in the art.

Then, a gate layer 24 is deposited on the gate dielectric layer 22. In this embodiment, the material of the gate layer 24 may be polycrystalline silicon, and its thickness may be about 10 nm to 100 nm; and in other embodiments, the material of the gate layer 24 may also be another material known to those skilled in the art, or, the gate layer 24 may have a multi-layered structure.

Step S2: a patterned hard mask layer 25 is formed on the gate layer 24, and a gate structure is formed by using the hard mask layer as an etch stop layer.

Specifically, referring to FIGS. 2a and 2b, a hard mask material layer (not shown in the figures) may be deposited on the gate layer 24, and then the hard mask material layer may be etched so as to form a hard mask layer 25 with a gate pattern (i.e., patterned hard mask layer). In this embodiment, the hard mask layer 25 may comprise a silicon oxide layer 251 and a silicon nitride layer 252 stacked sequentially, with the thickness of the silicon oxide layer 251 being about 5 nm to 30 nm, and the thickness of the silicon nitride layer 252 being about 10 nm to 70 nm.

Then, the patterned hard mask layer 25 may be used as an etch stop layer to etch the gate layer 24 and the gate dielectric layer 22, to form a gate structure. The gate structure may comprise a dummy gate 23 formed from etching the gate layer 24 and the etched gate dielectric layer 22.

Step S3, spacers 27 are formed on both sides of the gate structure, and a source/drain region 28 is formed.

Specifically, referring to FIG. 2c, spacers 27 may be formed on the sidewalls of the gate structure (the dummy gate 23 and the gate dielectric layer 22). In this embodiment, the spacers 27 may have a multi-layered structure, comprising a first spacer layer 271, a second spacer layer 272 and a third spacer layer 273 from inside to outside in that order. The first spacer layer 271 may join the dummy gate 23 at the outside of the dummy gate 23. The material of the first spacer 271 may be, e.g., silicon nitride (Si₃N₄) and its thickness may be about 5 nm to 15 nm. The second spacer layer 272 may be located at the outside of the first spacer layer 271, and the material of the second spacer layer 272 may be silicon oxide and the thickness may be about 2 nm to 10 nm. The third spacer layer 273 may be located at the outside of the second spacer layer 272, and the material of the third spacer layer 272 may be Si₃N₄ and the thickness may be about 10 nm to 40 nm. In other embodiments, the spacers 27 may have a single-layered or double-layered structure.

Then, ion implantation may be performed on the semiconductor substrate 20 by using the dummy gate 23 and the spacers 27 as a mask, to form a source region 281 and a drain region 282. In this embodiment, the source/drain region may also have a source/drain extension region, i.e., Lightly-Doped Drain (LDD) structure, and the source/drain extension region (not numbered in the figure) may be formed by lightly doping the semiconductor substrate 20 using the dummy gate 23 as a mask before formation of the spacers 27 and after formation of the dummy gate 23. In other embodiments, the source/drain extension region may be formed by performing the light doping during the forming of the spacers 27 after formation of the first spacer dielectric layer 271.

Step S4: a pre-metal dielectric layer 29 is deposited, and planarization is performed so that the dummy gate 23 is exposed.

Specifically, referring to FIG. 2d, after the formation of the source/drain region 28, a pre-metal dielectric layer 29 may be deposited, and the interlayer dielectric layer 29 may cover the surface of the semiconductor substrate 20 comprising the dummy gate 23 and the spacers 27. In this embodiment, the material of the pre-metal dielectric layer 29 may be silicon oxide, Si₃N₄, or another material known to those skilled in the art, e.g., any one or a combination of: PSG, BSG, FSG, and other low-K materials.

Then, the surface of the semiconductor substrate 20 may be planarized by Chemical Mechanical Polishing, which comprises two planarization processes. The first planarization process stops at the hard mask layer 25 (as shown in FIG. 2c), i.e., to remove the raised pre-metal dielectric layer; and the second planarization process stops at a surface of the dummy gate 23, i.e., to remove the hard mask layer 25.

Step S5: The dummy gate 23 is removed to form a gate groove 30, and a diffusion blocking layer 31 is formed in the gate groove 30.

Specifically, referring to FIG. 2e, the dummy gate 23 may be removed by dry-etching or wet-etching (as shown in FIG. 2d), i.e., to remove the polycrystalline silicon and expose the gate dielectric layer 22. In this embodiment, the high-K dielectric layer may be exposed at the bottom of the gate groove, and the sidewalls may be the exposed first spacer dielectric layer 271. In other embodiments, the high-K dielectric layer (It is noted that the dielectric layer may also be a gate dielectric layer of another material. This is similar in the following descriptions, and will not be noted again in the specification) may also be removed. Then, a high-K dielectric layer may need to be reformed before deposition of a diffusion blocking layer 31.

Then, a diffusion blocking layer 31 may be deposited in the gate groove 30. In this embodiment, for nMOS devices, the metal diffusion blocking layer 31 may have a single-layered structure such as TiAlN, or may have a multi-layered structure such as a two-layered structure formed by TiN and TiAlN stacked sequentially; and for pMOS devices, the metal diffusion blocking layer 31 may have a single-layered structure such as TiN, or may have a multi-layered structure such as two-layered structure formed by TaN and TiN stacked sequentially.

Step S6: a gate metal layer 32 is deposited on the surface of the substrate comprising the gate groove 30.

Specifically, referring to FIG. 2f, a metal layer 32 for manufacturing a metal gate may be deposited on a surface of the substrate by PVD or CVD, and the metal layer 32 may fill the gate groove 30 and cover the surface of the substrate that is outside the gate groove 30. At the 22 nm technology node and beyond, the critical dimension of gates is relatively small, resulting a relatively small width of the gate groove 30, and the ability of PVD or CVD deposition of a gate metal layer to fill a groove is relatively poor, therefore, gaps or holes 33 are often formed in the metal layer 32 when the gate groove 30 is filled with the metal layer 32.

The PVD process may be performed at a normal temperature or a raised temperature, or may be ionized PVD. Heated PVD and ionized PVD may provide a better hole-filling performance of the metal layer to some extent as compared with normal temperature PVD.

The material of the metal layer 32 may be Al, or a TiAlₓ alloy. When the material of the metal layer 32 is an alloy, the PVD process (e.g., magnetron sputtering) may use a corresponding alloy target or use a multi-metal target, and form an alloyed metal layer directly on the surface of the substrate.

Step S7: annealing is performed on the metal layer 32, to modify filling topography inside the gate groove.

Specifically, referring to FIG. 2g, the annealing process may be performed in a protective atmosphere, at a temperature lower than but close to the melting point of the metal layer (e.g., medium-temperature annealing), so that reflow occurs to the metal layer during the annealing process. The thicker metal at the opening of the gate groove (indicated by arrow A in the figure) reflows to the gaps or holes 33, thereby modifying the filling topography inside the gate groove, hence, the gate groove 30 is filled up and the gaps or holes 33 are eliminated.

In this embodiment, the protective atmosphere may be a N₂ or He atmosphere, and the annealing temperature may range from 300 to 600 degrees Celsius.

Step S8: the portion of the metal layer 32 that is outside the gate groove 30 is removed, to form a metal gate 34.

Specifically, referring to FIG. 2h, a planarization process may be performed on the surface of the substrate having the metal layer 32 and stop at a surface of the pre-metal dielectric layer 29, so as to remove the portion of the gate metal layer that is outside the gate groove 30, and form a metal gate 34.

It can be seen, by adding an annealing process after deposition of a metal layer, the method described above can improve hole-filling performance, reduce gaps and holes generated when filling the gate groove with the metal layer, facilitate reduction of the parasitic resistance of the gate, and improve the reliability of the transistor.

In the deposition process of the embodiment above, when the material of the metal layer is an alloy, the alloyed metal layer may be formed directly on the surface of the substrate. In fact, it may also be formed by: firstly depositing an element metal having a higher melting point of the two or more element metals in the alloy, and then depositing an element metal having a lower melting point in the alloy. This will be described below in detail in conjunction with the accompanying drawings in the following embodiment.

### Second embodiment

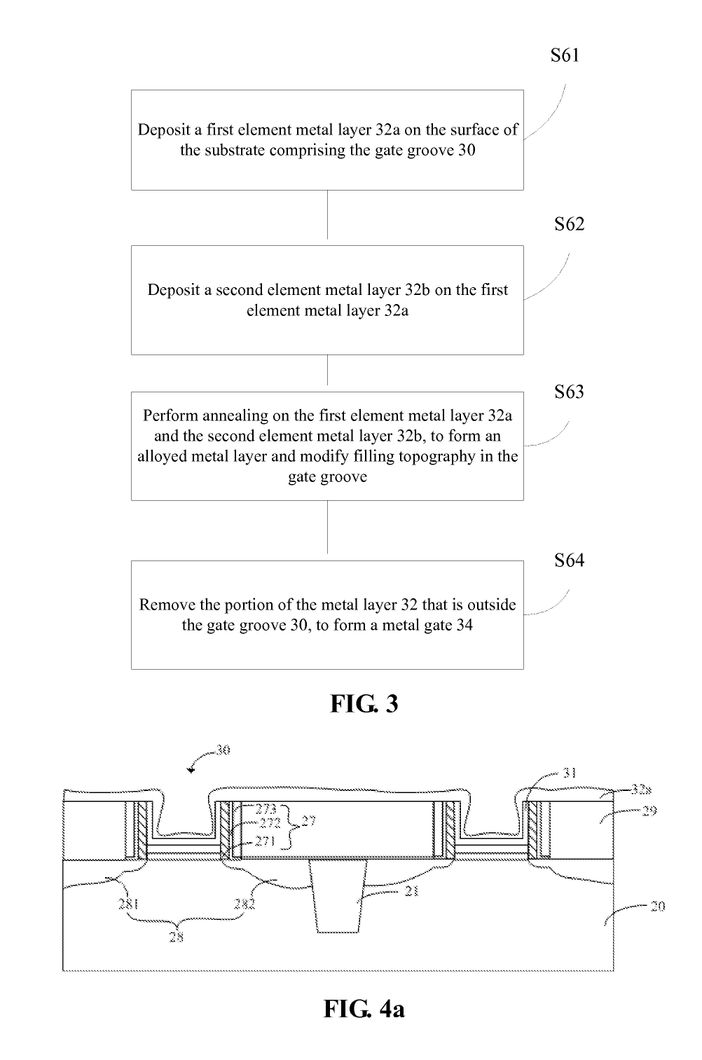

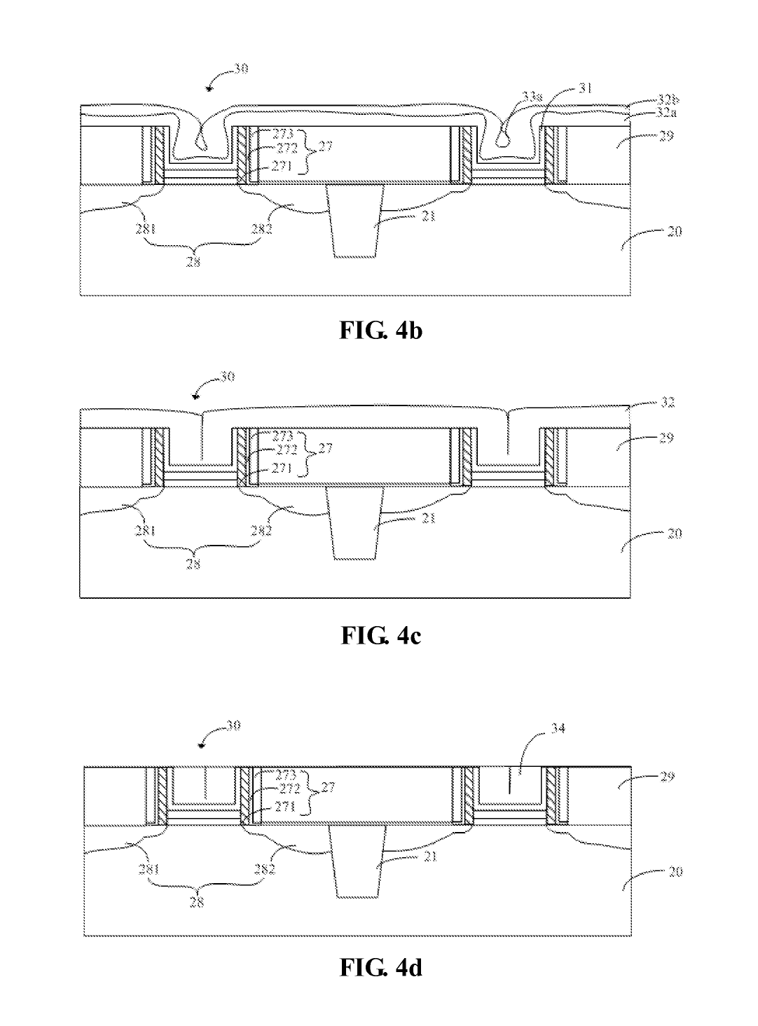

FIG. 3 is a flow chart of a method for manufacturing a metal gate in a gate-last process according to a second embodiment; and FIGS. 4a to 4d are schematic diagrams illustrating a method for manufacturing a metal gate in a gate-last process according to the second embodiment. In the method for manufacturing a metal gate in a gate-last process, the steps before deposition of a metal layer may be the same as or similar to those in the first embodiment (i.e., steps S1-S5 as shown in FIG. 2a-2e), which will be omitted here. The differences may exist in the steps after deposition of a metal layer, and that the material of the metal layer is an alloy comprising at least two element metals, for example, a TiAlₓ alloy in this embodiment.

The method comprises the following steps.

Step S61: a first element-metal layer 32a is deposited on the surface of the substrate comprising the gate groove 30.

Specifically, referring to FIG. 4a, a first element-metal layer 32a may be deposited by PVD or CVD. The material of the first element-metal layer 32a may be pure metal Ti, and its thickness may be 10 nm to 90 nm. The first element-metal layer 32a covers the inside of the gate groove 30 and the surface of the pre-metal dielectric layer 29 that is outside the gate groove 30; however, the first element-metal layer 32a does not fill the gate groove 30, it only covers the side walls and the bottom of the gate groove 30.

Step S62: a second element-metal layer 32b is deposited on the first element-metal layer 32a.

Specifically, referring to FIG. 4b, a second element-metal layer 32b may be deposited by PVD or CVD. The material of the second element-metal layer 32b may be pure metal Al and its thickness may be 10 nm to 90 nm. The second element-metal layer 32b covers the first element-metal layer 32a and fills the gate groove 30. At the 22 nm technology node and beyond, the critical dimension of gates is relatively small, resulting a relatively small width of the gate groove 30, and the ability of PVD or CVD deposition of a gate metal layer to fill a groove is relatively poor, therefore, gaps or holes 33 are often formed in the second element-metal layer 32b when the gate groove 30 is filled with the second element-metal layer 32b.

In steps S61-S62, the melting point of the material of the first element-metal layer is higher than that of the second element-metal layer, i.e., the element metal having a higher melting point in the alloy is deposited firstly, for example, in a TiAlₓ alloy metal Ti has a higher melting point than metal Al, thus the layer of Ti is deposited before the deposition of the layer of Al.

Step S63: annealing is performed on the first element-metal layer 32a and the second element-metal layer 32b, to form an alloyed metal layer and modify filling topography inside the gate groove.

Specifically, referring to FIG. 4c, the annealing process may be performed in a protective atmosphere, at a temperature lower than but close to the melting point of the second element-metal layer 32b (medium-temperature annealing), so that, on one hand, the first element-metal layer 32a alloys with the second element-metal layer 32b, to form a metal layer 32; and on the other hand, reflow occurs to the alloy during the annealing process, i.e., the thicker metal at the opening of the gate groove reflows to the gaps or holes 33a, thereby modifying the filling topography inside the gate groove, hence, the gate groove 30 is filled up and the gaps or holes 33 are eliminated.

In this embodiment, the protective atmosphere may be a N₂ or He atmosphere, and the annealing temperature may range from 300 to 600 degrees Celsius. The melting point of the first element-metal layer that is deposited firstly is higher than that of the second element-metal layer, and the second element metal also serves to improve shape-retaining performance of the filled metal.

Step S64: the portion of the metal layer 32 that is outside the gate groove 30 is removed, to form a metal gate 34.

Specifically, referring to FIG. 4d, a planarization process may be performed on the surface of the substrate having the metal layer 32, and stop at a surface of the pre-metal dielectric layer 29, so as to remove the portion of the metal layer that is outside the gate groove 30, and form a metal gate 34.

In this embodiment, the element metal having a higher melting point in a multi-element alloy (e.g., metal Ti in a TiAlₓ alloy) is deposited firstly; and then the element metal having a lower melting point in the alloy (e.g., metal Al in a TiAlₓ alloy) is deposited; then, a reflow process is performed by controlling the parameters such as temperature and time in a thermal processing process (e.g., annealing and reflow in a N₂ or He atmosphere at a temperature ranging from 300 to 600 degrees Celsius), and finally the objects of having the metal layers alloyed and filling with the metal material at a small technology node are achieved. It will be appreciated by those skilled in the art that based on the teaching of the embodiment, for three-element, four-element alloy or the like, the objects may also be achieved by the approach above with deposited element-metal layers, and in the process of deposition of the layers, the elemental metal layers are stacked from bottom to top in the order of decreasing melting points.

In the first and second embodiments above, the metal layer depositing-annealing process is performed for one cycle; and in the annealing process in the second embodiment, the deposition of the two single-element-metal layers is achieved with one alloying process. In fact, according to the method provided by the present invention, the metal gate may also be formed by performing the metal layer depositing-annealing process for multiple cycles, which will be described in detail in a third embodiment and a fourth embodiment.

### Third embodiment

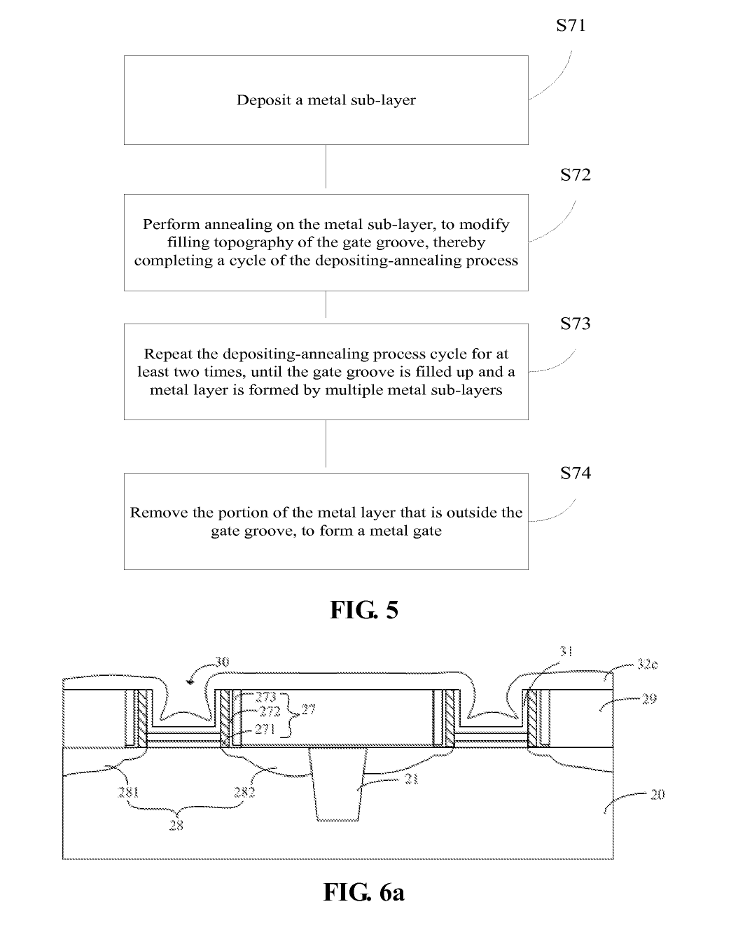

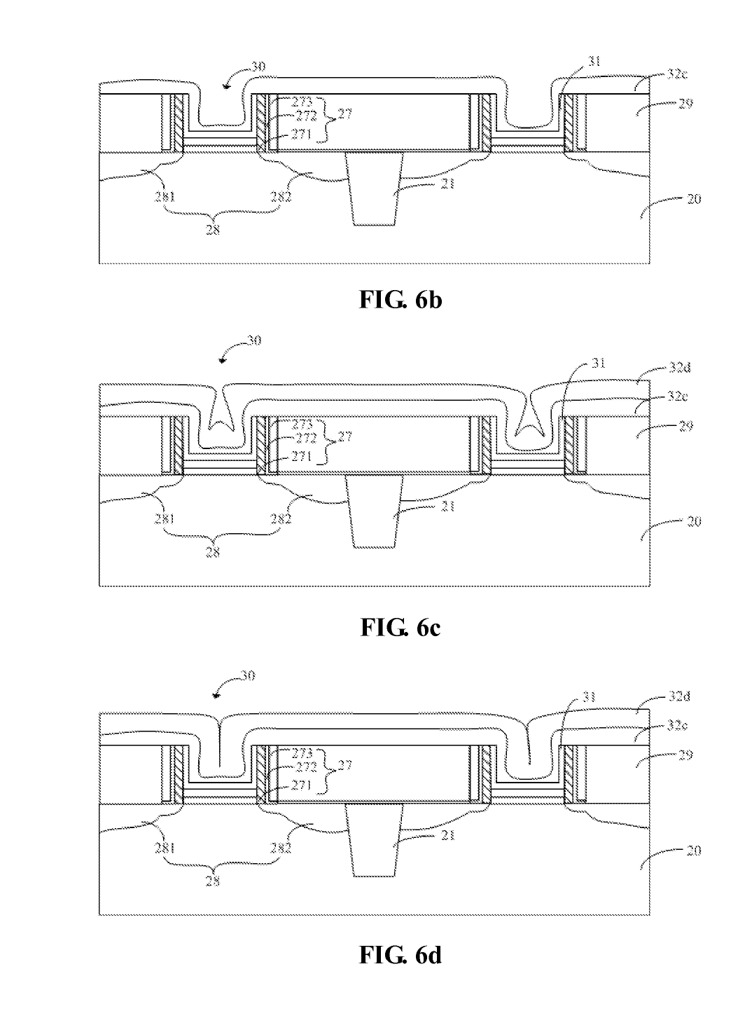

FIG. 5 is a flow chart of a method for manufacturing a metal gate in a gate-last process according to a third embodiment; and FIGS. 6a to 6d are schematic diagrams illustrating a method for manufacturing a metal gate in a gate-last process according to the third embodiment.

In the method for manufacturing a metal gate in a gate-last process, the steps before deposition of a metal layer may be the same as or similar to those in the first embodiment (i.e., steps S1-S5 as shown in FIG. 2a-2e), which will be omitted here. The differences may exist in the steps after deposition of a metal layer.

The method for manufacturing a metal gate in a gate-last process comprises the following steps.

Step S71: a metal sublayer is deposited.

Referring to FIG. 6a, a metal sublayer 32c for manufacturing a metal gate may be deposited on a surface of the substrate by PVD or CVD. The metal sublayer 32c covers the inside of the gate groove 30 and covers the surface of the substrate that is outside the gate groove 30. Its thickness is smaller than the width of the gate groove, hence multiple metal sublayers may need to be deposited to fill the gate groove. The material of the metal sublayer 32c may be a single-element metal or an alloy comprising at least two element metals.

Step S72: annealing is performed on the metal sublayer, to modify filling topography of the gate groove, thereby completing a cycle of the depositing-annealing process.

Referring to FIG. 6b, the annealing process is performed in a protective atmosphere, at a temperature lower than but close to the melting point of the metal sublayer (medium-temperature annealing), so that reflow occurs to the metal sublayer during the annealing process. The thicker metal at the opening of the gate groove reflows to the inside of the gate groove 30, thereby modifying the filling topography inside the gate groove, and covering the inside of the gate groove more uniformly. In this embodiment, the protective atmosphere may be a N₂ or He atmosphere, and the annealing temperature may range from 300 to 600 degrees Celsius. Steps S71-S72 forms one depositing-annealing process cycle.

Step S73: the depositing-annealing process cycle is repeated for at least two times, until the gate groove is filled up, and a metal layer is formed by multiple metal sublayers.

Referring to FIGS. 6c and 6d, another metal sublayer 32d is deposited, covering the metal sublayer 32c, and then an annealing process is performed on the metal sublayer 32d, to modify the filling topography inside the gate groove. The material of the metal sublayer 32d may be the same as that of the metal sublayer 32c, their thicknesses may also be the same or similar, and the parameters of the annealing processes may be substantially the same.

Step S74: the portion of the metal layer that is outside the gate groove is removed, to form a metal gate.

In this embodiment, by way of example, the depositing-annealing process is performed for two cycles; however in practice, the depositing-annealing process may be performed for more than two cycles according to design requirements.

As compared with the first embodiment, the process performed once in the first embodiment of depositing a metal layer and then performing an annealing process is performed for multiple cycles, and each of the cycles comprises depositing a metal sublayer and annealing it. The cycle is repeated for multiple times until the gate groove is filled up. By using the method according to this embodiment, an effect may be achieved that the metal layer is grown along with the modification of the filling topography of the gate groove, and by controlling the number of the deposited metal sublayers, the objects of full-filling and gaps and the holes eliminating can be achieved.

When the material of the metal sublayers is an alloy, in each of the depositing-annealing process cycles, the alloyed metal layer may be formed directly on the surface of the substrate. In fact, in each of the depositing-annealing process cycles, an element metal having a higher melting point of the two or more element metals in the alloy may be formed first, and then an element metal having a lower melting point in the alloy may be formed. This will be described below in detail in conjunction with the accompanying drawings in the following embodiment.

### Fourth embodiment

In the method for manufacturing a metal gate in a gate-last process, the steps before deposition of a metal layer may be the same as or similar to those in the first embodiment (i.e., steps S1-S5 as shown in FIG. 2a-2e). In contrast to the third embodiment, the material of the metal sublayer is an alloy comprising at least two element metals, and in one depositing-annealing process cycle, the first element-metal layer and the second element-metal layer are deposited sequentially, and then annealing is performed to form the alloyed metal layer and modify the filling topography.

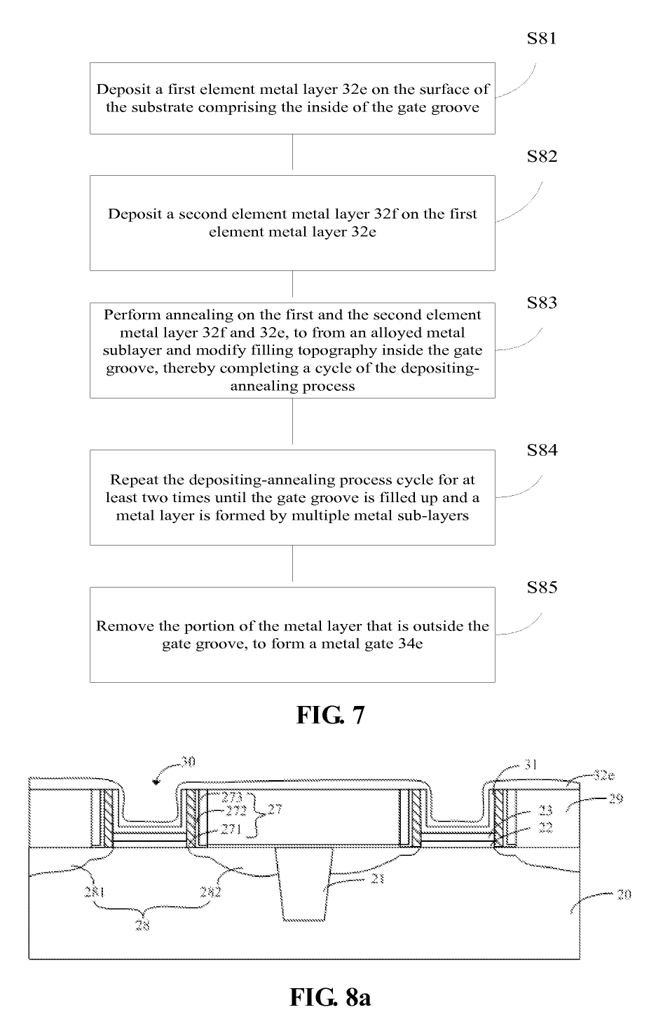

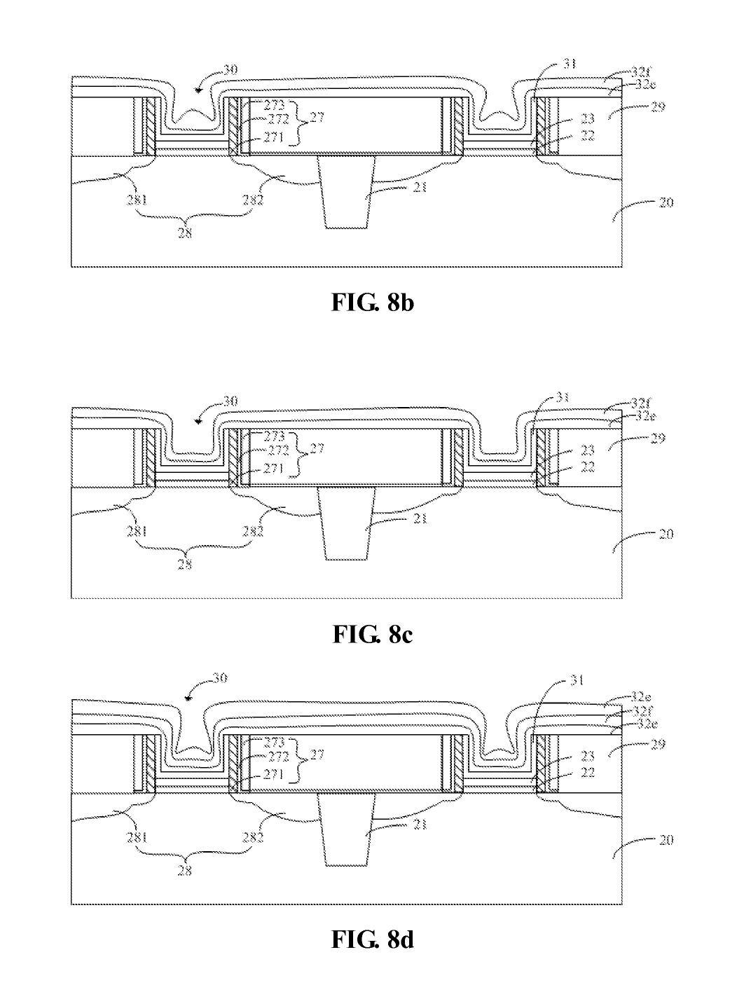

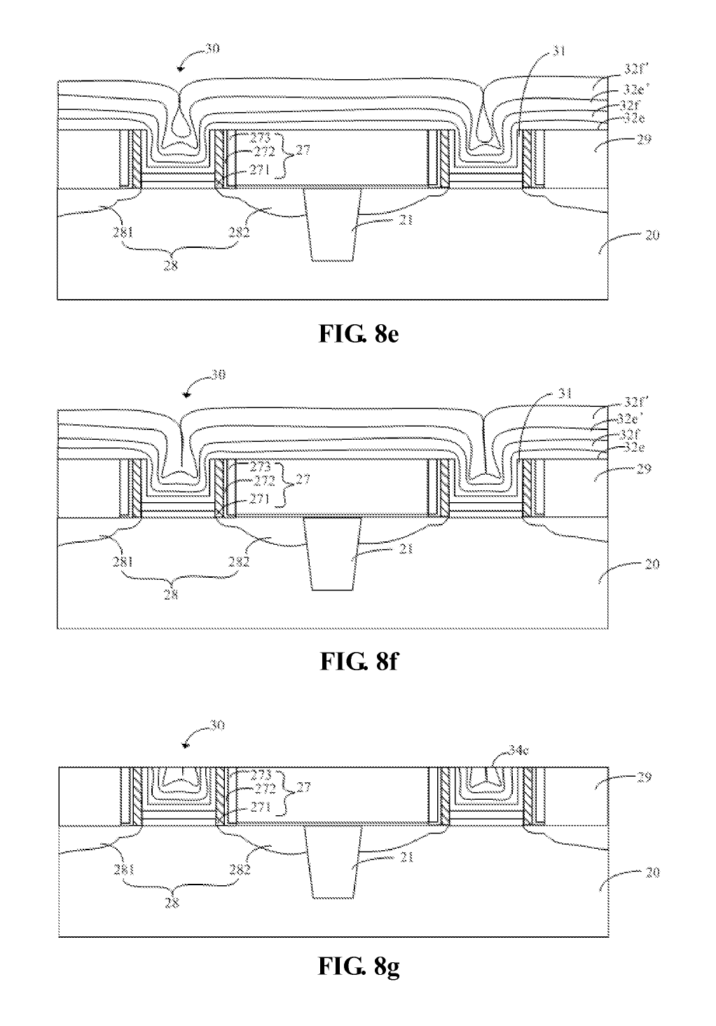

FIG. 7 is a flow chart of a method for manufacturing a metal gate in a gate-last process according to the fourth embodiment; and FIGS. 8a to 8g are schematic diagrams illustrating a method for manufacturing a metal gate in a gate-last process according to the first embodiment. In this method, the step of depositing a metal sublayer on a surface of the substrate comprises the following steps.

Step S81: a first element-metal layer 32e is deposited on the surface of the substrate comprising the inside of the gate groove, referring to FIG. 8a. The material of the first element-metal layer 32e may be Ti.

Step S82: a second element-metal layer 32f is formed on the first element-metal layer 32e, referring to FIG. 8b. The material of the second element-metal layer may be Al. The melting point of the first element-metal layer 32e is higher than that of the second element-metal layer 32f, and the thickness of the first and the second element-metal layer 32f and 32e is smaller than that of the width of the gate groove, hence the depositing process may need to be performed for multiple times to fill the gate groove.

Step S83: annealing is performed on the first and the second element-metal layer 32f and 32e, to form an alloyed metal sublayer and modify filling topography inside the gate groove, thereby completing a cycle of the depositing-annealing process, referring to FIG. 8c.

Step S84: the depositing-annealing process is performed for at least two cycles, until the gate groove is filled up and a metal layer is formed by multiple metal sublayers.

Referring to FIGS. 8d, 8e and 8f, a first element-metal layer 32e′ and a second element-metal layer 32f′ are deposited, and then annealing is performed, to modify the filling topography inside the gate groove; meanwhile, another metal layer is formed through alloying. The materials of the first element-metal layer 32e and 32e′, and the second element-metal layer 32f and 32f′ may be the same, their thicknesses may be the same or similar, and the parameters of the annealing processes may be substantially the same. After multiple depositing-annealing process cycles, a good metal-filling result may be obtained.

Step S85: the portion of the metal layer that is outside the gate groove is removed, to form a metal gate 34e, referring to FIG. 8g.

In this embodiment, the metal sublayer is a two-element alloy; and in other embodiment it may be an alloy of three or more elements, and the number of cycles performed of the depositing-annealing process may be determined as required in practice. In this embodiment, by way of example, the depositing-annealing process is performed for two cycles; and in other embodiments, the number of cycles may be three or more than three.

Preferred embodiments are described above for illustrative purposes. However, the scope of protection of the present invention is not limited to the detailed descriptions of the embodiments, and modifications may be made to the embodiments of the present invention by those skilled in the art without deviation from the scope of the present invention.

1. A method for manufacturing a metal gate in a gate-last process, comprising:
providing a substrate, the substrate comprising a gate groove;
performing a metal layer depositing-annealing process on a surface of the substrate for at least once, to fill the gate groove with a metal layer; and
removing a portion of the metal layer that is outside the gate groove.

2. The method for manufacturing a metal gate in a gate-last process according to claim 1, wherein the step of performing a metal layer depositing-annealing process on a surface of the substrate for at least once to fill the gate groove with a metal layer comprises:
depositing a metal layer on a surface of the substrate, to fill the gate groove; and
performing annealing on the metal layer, to modify filling topography inside the gate groove.

3. The method for manufacturing a metal gate in a gate-last process according to claim 2, wherein the material of the metal layer is Al or TiAlₓ.

4. The method for manufacturing a metal gate in a gate-last process according to claim 2, wherein the metal layer comprises:
at least two element-metal layers, the element-metal layers being stacked from bottom to top in the order of decreasing melting points.

5. The method for manufacturing a metal gate in a gate-last process according to claim 1, wherein the step of performing a metal layer depositing-annealing process on a surface of the substrate for at least once comprises the steps of:
depositing a metal sublayer on a surface of the substrate;
performing annealing on the metal sublayer, to modify filling topography of the metal sublayer, thereby completing a cycle of the depositing-annealing process; and
performing at least two cycles of the depositing-annealing process.

6. The method for manufacturing a metal gate in a gate-last process according to claim 5, wherein the material of the metal sublayer is Al or TiAlₓ.

7. The method for manufacturing a metal gate in a gate-last process according to claim 5, wherein the metal sublayer comprises:
at least two element-metal layers, the element-metal layers being stacked from bottom to top in the order of decreasing melting points.

8. The method for manufacturing a metal gate in a gate-last process according to claim 4, wherein the materials of the element-metal layers are Ti and Al from bottom to top.

9. The method for manufacturing a metal gate in a gate-last process according to claim 2, wherein the annealing is performed in N₂ or He.

10. The method for manufacturing a metal gate in a gate-last process according to claim 2, wherein the annealing is performed at a temperature ranging from 300 to 600 degrees Celsius.

11. The method for manufacturing a metal gate in a gate-last process according to claim 1, wherein Physical vapor deposition (PVD) or Chemical vapor deposition (CVD) is used to deposit the metal layer in the metal layer depositing-annealing process.

12. The method for manufacturing a metal gate in a gate-last process according to claim 7, wherein the materials of the element-metal layers are Ti and Al from bottom to top.

13. The method for manufacturing a metal gate in a gate-last process according to claim 5, wherein the annealing is performed in N₂ or He.

14. The method for manufacturing a metal gate in a gate-last process according to claim 5, wherein the annealing is performed at a temperature ranging from 300 to 600 degrees Celsius.
